(19) United States
(12) Patent Application Publication
(10) Pub. No.: US 2026/0255797 A1
(43) Pub. Date: Aug. 27, 2026

(54) Display Device

(71) Applicant: LG Display Co., Ltd., Seoul (KR)

(72) Inventors: Kyung Chul Ok, Paju-si (KR); Seung Chan Choi, Paju-si (KR); Woo Seok Jeong, Paju-si (KR); Jong Ho Kim, Paju-si (KR)

(21) Appl. No.: 19/395,879

(22) Filed: Nov. 20, 2025

(30) Foreign Application Priority Data
Jan. 24, 2025 (KR) 10-2025-0011985

(51) Int. Cl. H10K 59/121; H10K 59/122; H10K 59/124; H10K 59/126; H10K 59/65

(52) U.S. Cl. CPC H10K 59/1213; H10K 59/1216; H10K 59/122; H10K 59/124; H10K 59/126; H10K 59/65

(57) ABSTRACT

A display device presented herein includes a substrate including an active area with a sensor unit and a non-active area surrounding the active area, a sensor disposed under the substrate so as to correspond to the sensor unit, a light emitting device provided in the active area, the light emitting device including a plurality of first electrodes, an intermediate layer including a light emitting layer, and a second electrode, a transistor provided between the substrate and the light emitting device, and a light transmissive hydrogen collection pattern provided on the substrate so as to overlap the sensor.

### CROSS-REFERENCE TO RELATED APPLICATION

The present application claims priority to Republic of Korea Patent Application No. 10-2025-0011985, filed on January 24, 2025, which is hereby incorporated by reference in its entirety.

### BACKGROUND

The present disclosure relates to a display device, and more particularly to a display device with improved reliability.

Display devices for displaying images on TVs, monitors, smartphones, tablet computers, and laptop computers, etc. are used in various ways and forms.

A display device includes a plurality of pixels configured to display an image and a transistor configured to control the operation of each pixel.

Among display devices, a display device having a light emitting device in a display panel without a separate light source for compactness of the device and clear color display is considered to be a competitive application.

A display device is provided with a sensor for various purposes. As the integration of the display device increases, the sensor may be disposed overlapping or adjacent to an active area. In this case, deterioration of the characteristics of elements around the sensor becomes a problem.

Embodiments of the present disclosure provide a display device configured such that the light receiving capability of a sensor unit provided in an active area is maintained and the characteristics of a transistor around the sensor unit are stabilized.

Embodiments of the present disclosure provide a display device configured such that the reliability of a transistor including an oxide semiconductor is improved.

Embodiments of the present disclosure provide a display device configured such that the reliability of a transistor around a sensor unit that receives light is improved.

Embodiments of the present disclosure provide a display device configured such that a means for collecting residual hydrogen remaining in a sensor unit area where a shielding metal does not overlap is provided in order to receive light, whereby the reliability of the device is improved.

A display device according to one or more embodiments of the present disclosure includes a substrate including an active area including a sensor unit and a non-active area surrounding the active area, a sensor disposed under the substrate so as to correspond to the sensor unit, a light emitting device provided in the active area, the light emitting device including a plurality of first electrodes, an intermediate layer including a light emitting layer, and a second electrode, a transistor provided between the substrate and the light emitting device, and a light transmissive hydrogen collection pattern provided on the substrate so as to overlap the sensor.

A display device according to one or more other embodiments of the present disclosure includes a substrate including an active area and a non-active area surrounding the active area, wherein a plurality of subpixels are disposed in the active area, a sensor disposed under the substrate and further from a first subpixel of the plurality of subpixels than the substrate in a cross-sectional view of the display device, and one or more light transmissive hydrogen collection patterns overlapping a light receiving portion of the sensor. The one or more light transmissive hydrogen collection patterns propagate light to the light receiving portion of the sensor and collect residual hydrogen in an area overlapping the light receiving portion of the sensor. The first subpixel comprises a light emitting device configured to emit light and a driving transistor for driving the light emitting device. The driving transistor is between the substrate and the light emitting device in the cross-sectional view. The driving transistor includes a gate electrode, a source electrode, a drain electrode, and an active layer overlapping the gate electrode and connected to the source electrode and the drain electrode. A first hydrogen collection pattern of the one or more light transmissive hydrogen collection patterns is on a same layer as the active layer of the driving transistor.

### BRIEF DESCRIPTION OF THE DRAWINGS

The accompanying drawings, which are included to provide a further understanding of the present disclosure and are incorporated in and constitute a part of this disclosure, illustrate embodiment(s) of the present disclosure and together with the description serve to explain the principle of the present disclosure. In the drawings:

FIG. 1 is a schematic plan view showing a display device according to one or more embodiments of the present disclosure.

FIG. 2 is a circuit diagram showing a subpixel according to one or more embodiments of the present disclosure.

FIG. 3 is a plan view showing area B of FIG. 1.

FIG. 4 is a sectional view taken along line I-I’ of FIG. 3.

FIGS. 5 and 6 are sectional views showing a display device according to one or more other embodiments of the present disclosure.

FIGS. 7A and 7B show I-V graphs of surrounding transistors when a hydrogen collection pattern is not applied and when a hydrogen collection pattern is applied.

### DETAILED DESCRIPTION

Advantages and features of the disclosure, and implementation methods thereof, will be clarified through the following embodiments described with reference to the accompanying drawings. However, the disclosure may be embodied in different forms and should not be construed as limited to the embodiments set forth herein. Rather, these embodiments are provided so that the disclosure will be thorough and complete, and will fully convey the scope of the disclosure to those skilled in the art. Further, the disclosure is defined only by the categories of the claims.

The same reference numerals designate the same constituent elements. Thicknesses, ratios, and dimensions of constituent elements may be exaggeratedly expressed in the drawings, for effective description of the technical content. In addition, the dimensions and scales of constituent elements shown in the drawings are different from actual dimensions and scales, for convenience of description and, as such, the dimension scales of constituent elements are not limited to those shown in the drawings.

It will be understood that, when one constituent element (or an area, a layer, a portion, or the like) is referred to as being “disposed on”, “connected to” or “coupled to” another constituent element, the one constituent element may be directly connected/coupled to the other constituent element, or a third constituent element may be disposed between the two constituent elements.

The term “and/or” is used to include one or more combinations of associated configurations.

It will be understood that, although the terms “first”, “second”, etc. may be used herein to describe various elements, these elements should not be limited by these terms. These terms are only used to distinguish one element from another. For example, a first element referred to in the following description may represent a second element, without departing from the scope of the disclosure. Similarly, the second element may represent the first element. Unless clearly used otherwise, singular expressions include a plural meaning.

Terms such as "below," "lower," "above," and "upper" are used to describe the relationships between the components shown in the drawings. These terms are relative concepts and are explained based on the orientations indicated in the drawings. For instance, unless "directly" or "immediately" is used, one or more other components may be disposed between two parts. Spatially relative terms such as "below", “beneath”, "lower," "above," and "upper" may be employed to easily describe the correlation between one device or component and other devices or components, as represented in the drawings. These spatially relative terms should be understood as encompassing different orientations of the devices when used or during operation, in addition to the directions shown in the drawings. For example, if the device in one of the drawings is turned over, elements described as "below" or "beneath" other elements would then be oriented "above" the other elements. Therefore, the exemplary term "below" may encompass both downward and upward directions.

In this disclosure, it is to be understood that a term, such as “include”, “comprise” or “have”, is intended to designate that a characteristic, a number, a step, an operation, an element, a part or a combination of them described in the disclosure is present, and does not preclude the presence or addition possibility of one or more other characteristics, numbers, steps, operations, elements, parts, or combinations thereof.

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in a co-dependent relationship.

Hereinafter, a detailed description will be given of a display device according to embodiments of the present disclosure in conjunction with the attached drawings.

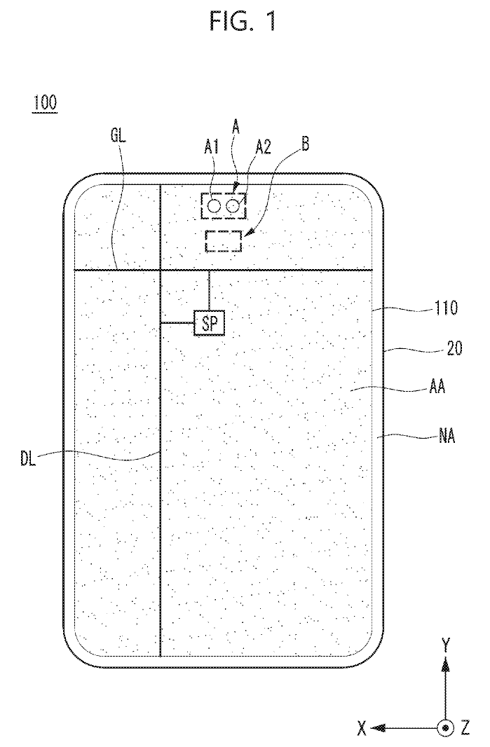

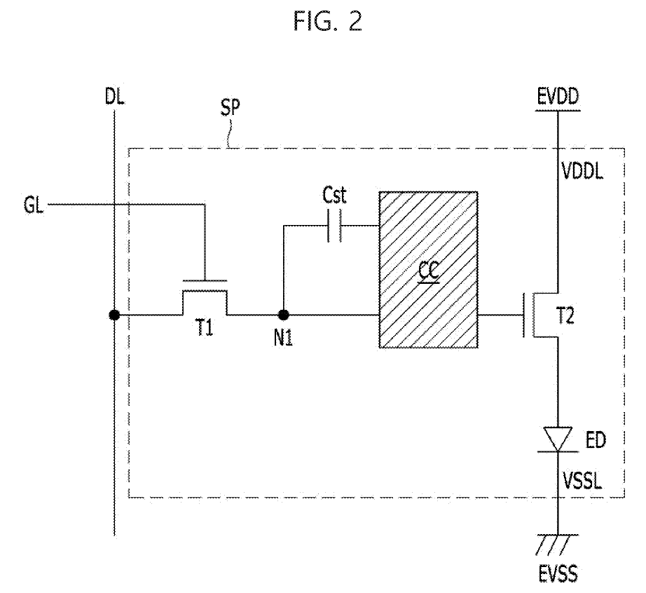

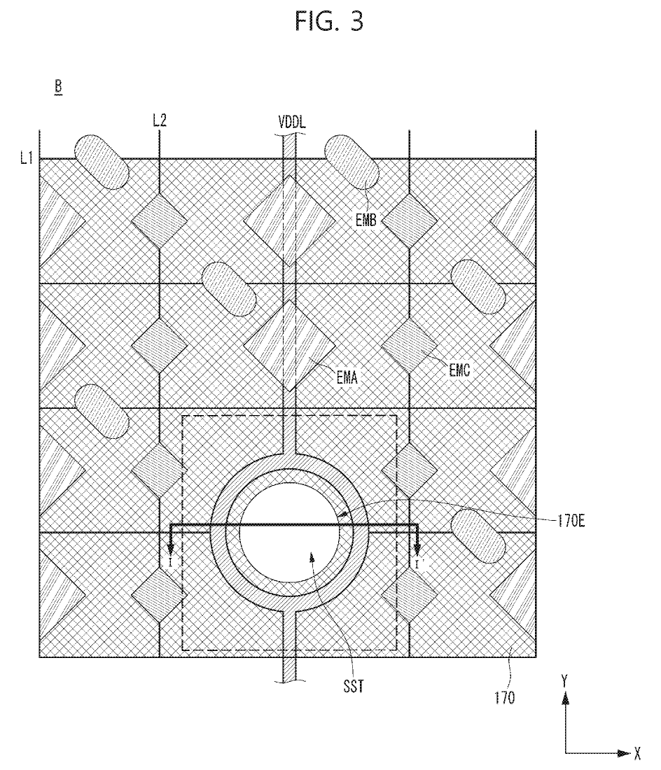

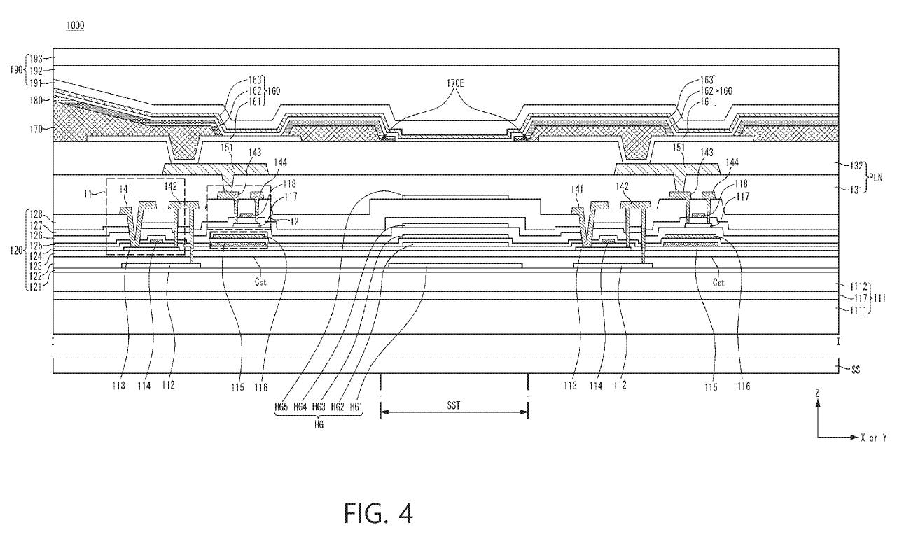

FIG. 1 is a schematic plan view showing a display device according to one or more embodiments of the present disclosure. FIG. 2 is a circuit diagram showing a subpixel according to one or more embodiments of the present disclosure. FIG. 3 is a plan view showing area B of FIG. 1. FIG. 4 is a sectional view taken along line I-I’ of FIG. 3.

Referring to FIG. 1, the display device 100 according to one or more embodiments of the present disclosure includes a display panel 110 including an active area AA and a non-active area NA and a cover member 20 disposed on the display panel 110.

The cover member 20 may be disposed on the display panel 110 so as to cover a front surface of the display panel 110 and may protect the display panel 110 from external impact. An edge portion of the cover member 20 may have a curvature portion or a curved surface portion bent in a direction toward a rear surface of the display device 100 (-Z axis direction). As a result, the cover member 20 may be disposed so as to cover a side surface area of the display panel 110 disposed on the rear surface, whereby the display panel 110 may be protected from external impact at not only the front surface but also the side surface of the display device 100.

The active area AA of the display device 100 may be an area for displaying an image, and an area other than the active area AA may be referred to as the non-active area NA. The active area AA is also referred to as a display area, and the non-active area NA is also referred to as a non-display area. The active area AA and the non-active area NA of the display device 100 may be equally applied to the display panel 110.

The display device 100 includes a substrate 111 (see FIGS. 4-6) having both the active area AA and the non-active area NA. A plurality of data lines DL extending in a first direction (e.g., a Y-axis direction) and a plurality of gate lines GL extending in a second direction (e.g., an X-axis direction) intersecting the first direction may be disposed in the active area AA on the substrate.

The areas delimited by the intersection of the data line DL and the gate line GL may each constitute one subpixel SP. One subpixel SP may be defined as the area in which a light emitting portion is disposed. In embodiments of the present disclosure, however, the light emitting portion is not necessarily limited to the area delimited by the intersection of the data line DL and the gate line GL. That is, at least a part of the light emitting portion may intersect the data line DL and/or the gate line GL.

For example, as shown in FIG. 2, a subpixel SP is disposed between a gate line GL and a data line DL that intersect each other, as shown in FIG. 3, and may include a first transistor T1, a second transistor T2, a storage capacitor Cst, a compensation circuit CC, and a light emitting device ED.

For example, the first transistor T1 may be a switching transistor, and the second transistor T2 may be a driving transistor.

Each of the first transistor T1 and the second transistor T2 may include an active layer, a gate electrode, and first and second source drain electrodes. The active layer of at least one of the first and second transistors T1 and T2 may include at least one of amorphous silicon, crystalline silicon, or an oxide semiconductor. The active layer of at least one of the first and second transistors T1 and T2 may include an oxide semiconductor. For example, the oxide semiconductor may include an oxide semiconductor material such as indium-gallium-zinc oxide (IGZO).

The first transistor T1 is electrically connected to a data line DL and is electrically connected to a first node N1. A gate electrode of the first transistor T1 is electrically connected to a gate line GL. The first transistor T1 transmits a data signal supplied via the data line DL to the first node N1 in response to a scan signal supplied via the gate line GL.

The storage capacitor Cst is electrically connected to the first node N1 to store voltage applied to the first node N1.

The second transistor T2 receives a high potential drive voltage EVDD, and is electrically connected to a first electrode (e.g., an anode) of the light emitting device ED. The second transistor T2 may control the amount of driving current flowing to the light emitting device ED in response to voltage applied to the gate electrode. The high potential drive voltage EVDD may be connected to the second transistor T2 via a first power supply voltage line VDDL.

The light emitting device ED outputs light corresponding to the driving current supplied from the second transistor T2. The light emitting device ED may output light corresponding to any one of red, green, blue, and white.

The light emitting device ED may include a first electrode, an intermediate layer disposed on the first electrode, and a second electrode. The second electrode of the light emitting device ED may be connected to a second power supply voltage line VSSL that supplies a low potential drive voltage EVSS. The second power supply voltage line VSSL is provided in the non-active area NA and may be connected to the second electrode. In some cases, the second power supply voltage line VSSL may also be provided in the active area AA to supply the low potential drive voltage EVSS to each subpixel SP or a plurality of subpixels SP and to uniformly maintain the potential of the second electrode for each subpixel.

The intermediate layer includes a light emitting layer and various functional layers, and may be configured to emit the same color of light on a pixel-by-pixel basis, such as white light, or may be configured to emit different colors on a subpixel-by-subpixel basis, such as red, green, or blue light. The functional layers may include a hole injection layer, a hole transport layer, an electron transport layer, an electron injection layer, and a charge generation layer. The intermediate layer may include a plurality of stacks, wherein the plurality of stacks may have a charge generation layer between adjacent stacks to facilitate the supply of holes and electrons to both stacks. Each of the plurality of stacks may include at least one light emitting layer, a hole transport layer, and an electron transport layer.

The first electrode of the light emitting device ED may function as an anode, and the second electrode may function as a cathode. The light emitting device ED is substantially the same as a light emitting device 160 (see FIG. 4) to be described later.

The compensation circuit CC may be provided in the subpixel SP to compensate for a threshold voltage of the second transistor T2. The compensation circuit CC may include one or more transistors. The compensation circuit CC may include one or more transistors and capacitors, and may be variously configured depending on a compensation method. The subpixel including the compensation circuit CC may include various structures, such as 3T1C, 4T2C, 5T2C, 6T1C, 6T2C, 7T1C, and 7T2C. For example, a plurality of transistors may be electrically connected between the second transistor T2 and the light emitting device ED.

FIG. 2 shows the configuration in which the second transistor T2 and the light emitting device ED are directly connected to each other, but embodiments of the present disclosure are not limited thereto. Depending on the form of the compensation circuit CC, the light emitting device ED may further include another transistor or a compensation capacitor between the light emitting device ED and the second transistor T2 generating the drive current.

Meanwhile, the display device 100 according to one or more embodiments of the present disclosure includes sensor units A and B provided in the active area AA.

The first sensor unit A may include a plurality of sensors A1 and A2. Examples of the plurality of sensors A1 and A2 include an image sensor or camera that receives image information, an infrared sensor that senses infrared light, and a fingerprint recognition sensor that senses fingerprint information. In FIG. 1, each of the sensors A1 and A2 is shown as having a circular shape, but the present disclosure is not necessarily limited thereto. The sensor may have a polygonal or elliptical shape. A light receiving area of each of the sensors A1 and A2 may be a part of the area occupied by each sensor.

Referring to FIGS. 1 and 3, the second sensor unit B may be disposed adjacent to the first sensor unit A or may be disposed independently. The second sensor unit B may include an RGB sensor that detects the color saturation of ambient light and/or an ambient light sensor that detects the brightness of ambient light. The second sensor unit B may be used to automatically adjust the brightness and color of the display device 100 by detecting the color saturation and brightness of ambient light. In the second sensor unit B, the sensor may be disposed under the substrate, but wiring or a shielding pattern may be omitted only for the light receiving portion SST of the sensor, and the subpixel density in the remaining area excluding the light receiving portion SST may be the same as the subpixel density in the surrounding active area. That is, the second sensor unit B may have the same wiring or transistor placement density in the area excluding the light receiving portion SST.

Here, the light receiving portion SST of the second sensor unit B is the area of a sensor SS that actually receives light from above, and, as shown in FIGS. 3 and 4, may be much narrower than the overlapping area between the sensor SS and the substrate 111.

Each of the first and second sensor units A and B may be disposed under the display panel 110 so as to overlap a part of the active area AA of the display panel 110.

As shown in FIGS. 3 and 4, a display device 1000 according to one or more embodiments of the present disclosure includes a substrate 111 including an active area AA including sensor units A and B (FIG. 1) and a non-active area NA surrounding the active area AA, sensors A1, A2, and SS disposed under the substrate 111 so as to correspond to the sensor units A and B, a light emitting device 160 provided in the active area AA, the light emitting device 160 including a plurality of first electrodes 161 an intermediate layer 162 including a light emitting layer, and a second electrode 163, transistors T1 and T2 provided between the substrate 111 and the light emitting device 160, and light transmissive hydrogen collection patterns HG (HG1, HG2, HG3, HG4, and HG5) provided on the substrate 111 so as to overlap the sensor SS.

The light transmissive hydrogen collection patterns HG (HG1, HG2, HG3, HG4, and HG5) may be provided on the same layer as the active layer or the electrode constituting the transistors T1 and T2 and the storage capacitor Cst.

Here, the light transmissive hydrogen collection patterns HG (HG1, HG2, HG3, HG4, and HG5) may be provided in the light receiving portion SST where light reception of the sensor SS is performed. The hydrogen collection patterns HG (HG1, HG2, HG3, HG4, and HG5) are disposed in the area where shielding metal patterns are omitted for the sensor SS to receive light. Each of the hydrogen collection patterns HG (HG1, HG2, HG3, HG4, and HG5) may include a material capable of transmitting light in the visible spectrum and having hydrogen collection ability, such as a transparent metal or a transparent semiconductor material. Therefore, light entering from above may be sensed by the sensor SS under the substrate 111 through the area overlapping the light transmissive hydrogen collection patterns HG (HG1, HG2, HG3, HG4, and HG5) on the light receiving portion SST.

The light transmissive hydrogen collection patterns HG (HG1, HG2, HG3, HG4, and HG5) transmit light in the visible spectrum. Therefore, when the sensors SS overlapping the light transmissive hydrogen collection patterns HG (HG1, HG2, HG3, HG4, and HG5) and the sensor SS overlapping the same sense the external light, the hydrogen remaining in the insulating layers 121, 122, 123, 124, 125, 126, 127, and 128 adjacent to the light transmissive hydrogen collection patterns HG (HG1, HG2, HG3, HG4, and HG5) may be captured, and the transistors T1 and T2 disposed in the area adjacent to the light receiving portion SST of the sensor unit may be prevented from being degraded by residual hydrogen.

FIG. 4 shows an example in which light transmissive hydrogen collection patterns HG (HG1, HG2, HG3, HG4, and HG5) are disposed overlapping in a pattern of multiple layers, but in some cases, only one thereof may be provided. Alternatively, two, three, or four of the light transmissive hydrogen collection patterns HG (HG1, HG2, HG3, HG4, and HG5) provided in FIG. 4 may be selectively provided, or all of the light transmissive hydrogen collection patterns HG (HG1, HG2, HG3, HG4, and HG5) provided in FIG. 4 may be provided.

Meanwhile, when each of the transistors T1 and T2 disposed on the substrate 111 includes an oxide semiconductor, a hydrogen collection pattern HG may be formed using an oxide semiconductor material in the same process. The oxide semiconductor material may include at least one of indium, gallium, zinc, and tungsten.

The light transmissive hydrogen collection patterns HG1, HG2, HG3, HG4, and HG5 may include a semiconductor or metal with an energy bandgap of 3.2 eV or more, enabling hydrogen capture in an electrically floating state.

For example, when the second transistor T2 includes an active layer 117 made of an oxide semiconductor, the first hydrogen collection pattern HG4 may be provided on the same layer as the active layer 117.

In addition to the first hydrogen collection pattern HG4 provided on the same layer as the active layer 117 of the second transistor T2, hydrogen collection patterns HG1, HG2, HG3, and HG5 provided on other layers may be included.

As shown in FIG. 4, the plurality of hydrogen collection patterns HG1, HG2, HG3, HG4, and HG5 may be provided on the insulating layer on which the electrode or active layer of each of the transistors T1 and T2 adjacent to or overlapping the sensor SS is disposed to effectively capture hydrogen remaining in each insulating layer of the substrate, thereby preventing a decrease in device reliability.

If the display device does not have a hydrogen collection pattern, hydrogen contained in the insulating layer of the substrate may flow into the transistors T1 and T2, especially a transistor including an oxide semiconductor. In this case, hydrogen may affect the conductivity of the active layer of the oxide semiconductor to reduce the channel area, to increase a threshold voltage dispersion range of the transistor, or to shift the threshold voltage in a negative direction, thereby lowering the reliability of the off characteristics of the transistor.

In the display device according to one or more embodiments of the present disclosure, the light transmissive hydrogen collection patterns HG (HG1, HG2, HG3, HG4, and HG5) are provided to reduce the fluctuation of the threshold voltage of the transistor, thereby narrowing the threshold voltage dispersion range and improving the reliability of the transistor.

The plurality of light transmissive hydrogen collection patterns HG1, HG2, HG3, HG4, and HG5 may overlap each other. In some cases, a part of at least one of the light transmissive hydrogen collection patterns HG1, HG2, HG3, HG4, and HG5 may overlap the light receiving portion SST and the rest may extend to the outside of the light receiving portion SST. Some of the light transmissive hydrogen collection patterns may include areas that do not overlap the other light transmissive hydrogen collection patterns.

In some cases, the hydrogen collection patterns HG1, HG2, HG3, and HG5 may be formed not only in the active layer 117 made of the oxide semiconductor but also in the metal layer of the same layer as other electrode layers forming the transistor, and hydrogen generated during the process may be captured by the hydrogen collection patterns HG1, HG2, HG3, and HG5, and after completing the formation of the transistors T1 and T2, the metallic hydrogen collection patterns HG1, HG2, HG3, and HG5 may be removed.

The metal having the hydrogen collection function may be, for example, titanium (Ti), a titanium alloy, or a stack structure of Ti/Al/Ti.

In some cases, the hydrogen collection patterns HG (HG1, HG2, HG3, HG4, and HG5) may be provided as patterns during the process and then removed together in the pattern process of the metal layer. In this case, the light receiving degree of the light receiving portion SST of the sensor unit at which light is sensed may be maintained because the pattern of the metal layer is removed.

FIG. 4 shows an example in which the plurality of light transmissive hydrogen collection patterns (HG (HG1, HG2, HG3, HG4, and HG5) is stacked. When these patterns are left in the display device 1000, each of the pattern layers HG1, HG2, HG3, HG4, and HG5 may include an oxide semiconductor such that that light can pass through the light receiving portion SST. In this case, each of the pattern layers HG1, HG2, HG3, HG4, and HG5 may not be the same material as the active layer included in the transistors T1 and T2. Each of the light transmissive hydrogen collection patterns HG (HG1, HG2, HG3, HG4, and HG5) left in the display device 1000 is an oxide semiconductor layer, which may include at least one of oxygen, indium, gallium, zinc, and tungsten.

Alternatively, each of the light transmissive hydrogen collection patterns HG (HG1, HG2, HG3, HG4, and HG5) may include a metal that is light transmissive in the visible spectrum.

Alternatively, each of the light transmissive hydrogen collection patterns HG (HG1, HG2, HG3, HG4, and HG5) may include a semiconductor or metal having an energy bandgap of 3.2 eV or more. This property is necessary for the sensor SS provided under the substrate 111 to receive light from above.

Hereinafter, the configuration around the light transmissive hydrogen collection patterns HG (HG1, HG2, HG3, HG4, and HG5) will be described with reference to the drawings.

As shown in FIG. 3, the second sensor unit B is an area including an RGB sensor that detects the color saturation of ambient light and/or an ambient light sensor that detects the brightness of ambient light.

As shown in FIG. 3, since the second sensor unit B detects ambient light in the area where the sensor SS is located and an image is not directly displayed in that area, light emitting portions EMA, EMB, and EMC and first and second wirings L1 and L2 may be regularly disposed around the light receiving portion SST of the sensor SS.

Referring to FIG. 4, the sensor SS, such as an RGB sensor or an ambient light sensor may be disposed under the substrate 111.

The sensor SS may be further provided with an opening having a size corresponding to the light receiving portion SST of the sensor SS in a light shielding bank 170 having openings for the light emitting portions EMA, EMB, and EMC on the substrate 111 to increase the transmittance of ambient light.

Although the light receiving portion SST of the sensor unit is shown as a circular shape in FIG. 3, embodiments of the present disclosure are not limited thereto. The light receiving portion SST may be elliptical or may be a polygonal shape including straight lines and curved lines. The size and shape of the light receiving portion SST may be adjusted according to the light receiving area and light receiving sensitivity of the sensor SS.

As shown in FIGS. 3 and 4, an end line 170E of the light shielding bank 170 is adjacent to the vicinity of the light receiving portion SST of the sensor, and the light shielding bank 170 is removed from the light receiving portion SST of the sensor. The light receiving portion SST of the sensor is left as a light transmissive layer constituting the substrate 111 and the upper part of the substrate 111, whereby ambient light entering from above may be sensed under the substrate 111 without any restriction on the transmittance.

Meanwhile, as shown in FIG. 3, the light receiving portion SST may be disposed so as not to overlap the wiring, thereby enhancing the sensing sensitivity of the sensor SS.

FIG. 3 shows an embodiment in which a high potential voltage line VDDL is disposed around the light receiving portion SST so as to surround the light receiving portion SST. The high potential voltage line VDDL may be disposed outside the light receiving unit SST in the Y-axis direction.

This is an example, and another power supply voltage line, such as a low potential voltage line VSSL, a data line DL, or a gate line GL, or an emission control line may be further disposed around the light receiving portion SST.

Referring to FIG. 4, a plurality of subpixels SP may be provided in the active area AA of the substrate 111, and the plurality of subpixels SP may also be included in the second sensor unit B.

The substrate 111 may be made of a flexible material, and may include first and second organic layers 1111 and 1112 overlapping each other with an inorganic interlayer insulating layer 117 therebetween. The inorganic interlayer insulating layer 117 may have the function of blocking the transfer of moisture or impurities between the first and second organic layers 1111 and 1112. The inorganic interlayer insulating layer 117 may be formed on the first organic layer 1111, and may be partially patterned. The inorganic interlayer insulating layer 117 may include at least one of a silicon nitride layer, a silicon oxide layer, and a silicon oxynitride layer.

The first and second organic layers 1111 and 1112 may include, for example, polyimide. In addition to polyimide, the first and second organic layers 1111 and 1112 may include different organic layers.

The substrate 111 may include one of the first and second organic layers 1111 and 1112 as polyethylene terephthalate (PET) and the other as polyimide.

In another embodiment, the substrate 111 may include a flexible, thin glass material.

The substrate 111 serves to support and protect the components of the display device disposed thereon.

In the active area AA and the non-active area NA of the substrate 111, a plurality of stacked insulating layers 120 (121, 122, 123, 124, 125, 126, 126, 127, and 128) and planarization layers PLN (151 and 152) are disposed.

Shielding patterns 112 and 116 and active layers 113 and 117 of the transistors T1 and T2 are insulated from each other, the active layers 113 and 117 and the gate electrodes 114 and 118 are insulated from each other, and the gate electrodes 114 and 118 and the source drain electrodes 141, 142, 143, and 144 are insulated from each other.

A fifth insulating layer 125 may be provided between a first storage electrode 115 and a second storage electrode 116 constituting the storage capacitor Cst.

The first storage electrode 115 and the second storage electrode 116 may function as a shielding pattern for the second transistor T2.

The first shielding pattern 112 is disposed under the first transistor T1 to prevent the effects by light directed toward the first active layer 113 from the lower side of the substrate 111.

In one or more embodiments, the first transistor T1 includes a first active layer 113, a first gate electrode 114, and first and second source drain electrodes 141 and 142. The first shielding pattern 112 may be connected to one side of the first active layer 113 via the second source drain electrode 142, as shown. In some cases, the first gate electrode 114 of the first transistor T1 may be connected to the first shielding pattern 112 via another connection electrode, whereby the first shielding pattern 112 may function as a double gate together with the first gate electrode 114. In the double gate structure, the same gate voltage may be applied to the first shielding pattern 112 and the first gate electrode 114.

An insulating layer 125 may be interposed between the first storage electrode 115 and the second storage electrode 116, which overlap each other, to constitute a storage capacitor Cst.

In one or more embodiments, the second transistor T2 includes a second active layer 117, a second gate electrode 118, a third source drain electrode 143, and a fourth source drain electrode 144. The first storage electrode 115 and the second storage electrode 116 may function as a shielding pattern for the second transistor T2.

The second transistor T2 may be connected to the first electrode 161 of the light emitting device ED 160 via a connection electrode 151.

Meanwhile, the circuit configuration of the subpixel in the second sensor unit B shown is an example, and the configuration of the transistor and the capacitor may be modified or added.

In the display device according to one or more embodiments of the present disclosure, the light transmissive collection patterns HG may be provided in the light receiving portion SST of the sensor unit B (see FIG. 3) so as to leave shielding patterns empty for light reception.

The insulating layer 120 provided on the substrate 111 may include, for example, a first insulating layer 121, a second insulating layer 122, a third insulating layer 123, a fourth insulating layer 124, a fifth insulating layer 125, a sixth insulating layer 126, a seventh insulating layer 127, and an eighth insulating layer 128. The insulating layer 120 may include an inorganic insulating material.

The first insulating layer 121 is disposed in the active area AA and the non-active area NA of the substrate 111. The first insulating layer 121 may be referred to as a buffer layer and may perform the same function as a buffer layer. The first insulating layer 121 may be disposed on the substrate 111 to protect structures located on the substrate 111 from moisture permeating through the substrate 111 and to planarize the surface of the substrate 111. The first insulating layer 121 may include a plurality of inorganic insulating layers.

The first insulating layer 121 may extend to an edge the non-active area NA of the substrate 111 to prevent permeation of moisture from the edge of the substrate 111. The first insulating layer 121 may be constituted by a single inorganic layer or a plurality of alternately stacked inorganic layers.

For example, the first insulating layer 121 may include at least one of a silicon oxide (SiOx) layer, a silicon nitride (SiNx) layer, and a silicon oxynitride (SiOxNy) layer, or a multilayer layer formed by stacking the inorganic layers.

For example, the first shielding pattern 112 may be provided on the first insulating layer 121. For example, the first shielding pattern 112 may be made of a conductive metal material. Specifically, the conductive metal material may include at least one of an aluminum-based metal, such as aluminum (Al) or an aluminum alloy, a silver-based metal, such as silver (Ag) or a silver alloy, a copper-based metal, such as copper (Cu) or a copper alloy, a molybdenum-based metal, such as molybdenum (Mo) or a molybdenum alloy, chromium (Cr), tantalum (Ta), neodymium (Nd), and titanium (Ti).

The second light transmissive hydrogen collection pattern HG1 may be provided on the same layer as the first shielding pattern 112.

The second insulating layer 122 may be disposed on the first insulating layer 121. The second insulating layer 122 may function, for example, as a second buffer layer. A polysilicon-type transistor having an active layer made of crystalline silicon may be included as a transistor provided on the substrate 111. In this case, the second insulating layer 122 may stabilize and planarize a formation surface of the active layer including crystalline silicon. The second insulating layer 122 may include an inorganic layer, such as a silicon oxide (SiOx) layer, a silicon nitride (SiNx) layer, or a multilayer layer thereof.

The third insulating layer 123, which functions as a buffer layer for the first active layer 113, may be further provided on the second insulating layer 122. The third insulating layer 123 may include an inorganic layer, such as a silicon oxide (SiOx) layer, a silicon nitride (SiNx) layer, or a multilayer layer thereof.

The first active layer 113 including crystalline silicon may be provided on the third insulating layer 123. The first active layer 113 may be formed, for example, by first forming amorphous silicon on the entire surface of the third insulating layer 123 and then crystallizing the same through a laser irradiation process to form crystalline silicon.

The fourth insulating layer 124 may be provided on the third insulating layer 123 so as to cover the first active layer 113. The fourth insulating layer 124 may be used as a gate insulating layer for the first transistor T1 including crystalline silicon as the first active layer 113.

The first gate electrode 114 of the first transistor T1 and the first storage electrode 115 of the storage capacitor Cst may be provided on the fourth insulating layer 124. A third light transmissive hydrogen collection pattern HG2 may be provided on the same layer.

Each of the first gate electrode 114 and the first storage electrode 115 may be made of, for example, a shielding conductive metal material. Specifically, the shielding conductive metal material may include at least one of an aluminum-based metal, such as aluminum (Al) or an aluminum alloy, a silver-based metal, such as silver (Ag) or a silver alloy, a copper-based metal, such as copper (Cu) or a copper alloy, a molybdenum-based metal, such as molybdenum (Mo) or a molybdenum alloy, chromium (Cr), tantalum (Ta), neodymium (Nd), and titanium (Ti).

The fifth insulating layer 125 may be disposed on the fourth insulating layer 124 so as to cover the first gate electrode 114 and the first storage electrode 115. The fifth insulating layer 125 may function as an insulator between the first and second storage electrodes 115 and 116 and may also function as the interlayer insulating layer of the first transistor T1 including polycrystalline silicon as the first active layer 113.

The fifth insulating layer 125 may include an inorganic material. The inorganic material may include, for example, a silicon nitride (SiNx) layer or a silicon oxide (SiOx) layer.

The second storage electrode 118, which is made of a conductive metal material, may be formed on the fifth insulating layer 125 so as to overlap the first storage electrode 115. Specifically, the conductive metal material may include at least one of an aluminum-based metal, such as aluminum (Al) or an aluminum alloy, a silver-based metal, such as silver (Ag) or a silver alloy, a copper-based metal, such as copper (Cu) or a copper alloy, a molybdenum-based metal, such as molybdenum (Mo) or a molybdenum alloy, chromium (Cr), tantalum (Ta), neodymium (Nd), and titanium (Ti). A fourth light transmissive hydrogen collection pattern HG3 may be provided on the same layer as the second storage electrode 116.

Each of the first storage electrode 115 and the second storage electrode 116 may be a single layer, or may have a structure in which a plurality of different metal materials is stacked.

The sixth insulating layer 126 may be disposed on the fifth insulating layer 125 on which the second storage electrode 116 is disposed. An inorganic insulating material of the sixth insulating layer 126 may be used to planarize a formation surface of the second transistor T2. The sixth insulating layer 126 may include a single layer of an inorganic insulating material including a silicon oxide (SiOx) layer or a multilayer layer in which a silicon oxide layer and other inorganic insulating layers are stacked.

The sixth insulating layer 126 is located under the second active layer 117 and functions as a buffer layer, and may also planarize a formation surface of the second active layer 117. The sixth insulating layer 126 does not emit hydrogen particles during heat treatment, and therefore it is possible to prevent a decrease in reliability of the second active layer 117 of the oxide semiconductor layer, disposed on the sixth insulating layer 126 so as to be adjacent thereto, due to hydrogen particles.

The second active layer 117 of the second transistor T2 may be disposed on the sixth insulating layer 126. The second active layer 117 may include, for example, an oxide semiconductor material. The oxide semiconductor material may include a combination of at least one of zinc (Zn), indium (In), gallium (Ga), tin (Sn), and titanium (Ti) and an oxide. In some cases, a highly conductive metal, such as iron (Fe), may be further included in the oxide semiconductor material to increase mobility. A first light transmissive hydrogen collection pattern HG4 made of the same oxide semiconductor material may be provided on the same layer as the second active layer 117.

More specifically, the oxide semiconductor material constituting the second active layer 117 may be, for example, zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), or iron-indium-zinc oxide (FIZO).

The seventh insulating layer 127 may be disposed so as to cover the second active layer 117. The seventh insulating layer 127 may include a silicon oxide layer or a silicon nitride layer. The seventh insulating layer 127 may function as a gate insulating layer for the second transistor T2.

A conductive metal material is deposited on the seventh insulating layer 127 in order to form the second gate electrode 118.

The conductive metal material forming the second gate electrode 118 may include at least one of an aluminum-based metal, such as aluminum (Al) or an aluminum alloy, a silver-based metal, such as silver (Ag) or a silver alloy, a copper-based metal, such as copper (Cu) or a copper alloy, a molybdenum-based metal, such as molybdenum (Mo) or a molybdenum alloy, chromium (Cr), tantalum (Ta), neodymium (Nd), and titanium (Ti).

A light transmissive hydrogen collection pattern may be further provided on the same layer as the seventh insulating layer 127 on which the second gate electrode 118 is disposed.

The eighth insulating layer 128 is disposed so as to cover the second gate electrode 118.

For example, in the eighth insulating layer 128, a plurality of inorganic insulating layers may be stacked to maintain interlayer insulation between the second gate electrode 118 and the third and fourth source drain electrodes 143 and 144 and to planarize a formation surface where the third and fourth source drain electrodes 143 and 144 are formed.

The fifth to eighth insulating layers 125, 126, 127, and 128 are selectively removed together from the upper parts of the second active layer 117 on both sides to expose holes exposing the upper parts of the first active layer 113 on both sides. At the same time, the seventh and eighth insulating layers 127 and 128 are selectively removed together from the upper parts of the second active layer 117 on both sides to expose holes exposing the upper parts of the second active layer 117 on both sides. In the same process, holes formed through the second to eighth insulating layers 122, 123, 124, 125, 126, 127, and 128 may also be provided so as to expose a predetermined region of the first shielding pattern 112 protruding laterally beyond the first active layer 113.

A conductive metal material is deposited on the eighth insulating layer 128 in order to form the first and second source drain electrodes 141 and 142 of the first transistor T1 and the third and fourth source drain electrodes 143 and 144 of the second transistor. A photosensitive resist is applied to the conductive metal material, exposed, and developed to selectively leave the resist pattern at the formation regions of the first to fourth source drain electrodes 141, 142, 143, and 144. The conductive metal material is patterned using the resist pattern to form the first to fourth source drain electrodes 141, 142, 143, and 144.

Here, the first and second source drain electrodes 141 and 142 are connected to the upper parts of the first active layer 113 on both sides via contact holes formed through the fifth to eighth insulating layers 125, 126, 127, and 128. The second source drain electrode 142 may extend so as to overlap the first shielding pattern 112 protruding laterally beyond the first active layer 113, may be connected to the first shielding pattern 112 via contact holes formed through the second to eighth insulating layers 122, 123, 124, 125, 126, 127, and 128, and may stabilize the potential of the first shielding pattern 112.

The third and fourth source drain electrodes 143 and 144 are connected to the upper parts of the second active layer 117 on both sides via contact holes formed through the seventh and eighth insulating layers 127 and 128. The third source drain electrode 143 is connected to the connecting electrode 151 disposed thereon, and may have a larger width than the fourth source drain electrode 144.

Subsequently, a planarization layer PLN may be provided on the eighth insulating layer 128 in order to planarize the surface where the light emitting device 160 is formed.

For example, the planarization layer PLN may include a first planarization layer 131 and a second planarization layer 132.

Each of the first and second planarization layers 131 and 132 may be made of an organic material. The organic material constituting each of the first and second planarization layers 131 and 132 may include at least one of an acryl resin, a phenolic resin, a polyimide resin, an unsaturated polyester resin, a polyamide resin, benzocyclobutene, a polyphenylene resin, and a polyphenylene sulfide resin. Each of the first and second planarization layers 131 and 132 is thicker than each of the first to eighth insulating layers 121, 122, 123, 124, 125, 126, 127, and 128, which is advantageous for planarization.

After application of the first planarization layer 131, a contact hole is formed so as to expose the third source drain electrode 143 of the second transistor T2.

The connection electrode 151 provided on the first planarization layer 131 may be connected to the third source drain electrode 143 via the contact hole exposing the third source drain electrode 143.

In one or more embodiments, the connection electrode 151 may be made of any one selected from the group consisting of molybdenum (Mo), aluminum (Al), chromium (Cr), gold (Au), titanium (Ti), nickel (Ni), neodymium (Nd), and copper (Cu) or an alloy thereof. However, embodiments of the present disclosure are not limited thereto. In some cases, the connection electrode 151 may be omitted.

When the connecting electrode 151 is omitted, the third source drain electrode 143 may be directly connected to the first electrode 161 of the light emitting device 160.

The light emitting device 160 includes a first electrode 161, an intermediate layer 162, and a second electrode 163. The first electrode 161 is independently provided for each subpixel SP and may be separated from first electrodes of subpixels adjacent thereto.

In one or more embodiments, the first electrode 161 may include a metal material with high reflectivity or a transparent electrode. For example, the first electrode 161 may have a single layer of a transparent conductive layer such as ITO (indium tin oxide), IZO (indium zinc oxide), TO (tin oxide), or ITZO (indium tin zinc oxide), may have a multilayer structure of aluminum (Al) and titanium (Ti) (Ti/Al/Ti), a multilayer structure of aluminum (Al) and ITO (ITO/Al/ITO), an APC (Ag/Pd/Cu) alloy, and a multilayer structure of an APC alloy and ITO (ITO/APC/ITO), or a multilayer structure of silver (Ag) and a molybdenum/titanium alloy (Ag/MoTi), or may have a single layer of any one selected from among silver (Ag), aluminum (Al), molybdenum (Mo), gold (Au), magnesium (Mg), calcium (Ca), and barium (Ba) or an alloy of two or more thereof. When the first electrode 161 has a single layer of a transparent conductive layer, light emitted from the light emitting device 160 may be emitted through the first electrode 161. When the first electrode 161 includes a reflective electrode, light may be emitted through the second electrode 163 opposite the first electrode 161.

The first electrode 161 may include, for example, a reflective electrode and may function to prevent incidence of light on the transistors T1 and T2 under the light emitting device 160. The first electrode 161 may include, for example, a structure in which a first transparent electrode, a reflective electrode, and a second transparent electrode are stacked. The second transparent electrode, which is the uppermost electrode of the first electrode 161, may be a dielectric, which may lower the barrier to hole injection at the interface with the intermediate layer 162. Here, each of the first and second transparent electrodes may be a transparent oxide electrode such as ITO or IZO. The reflective electrode may include silver, a silver alloy such as APC (Ag-Pd-Cu), aluminum, or an aluminum alloy.

In a top emission type light emitting display device, the second electrode 163 may include a transparent electrode or a thin transflective electrode capable of light transmission such that light can be transmitted through the second electrode 163. The transparent electrode may be made of, for example, ITO or IZO, and the transflective electrode may be made of, for example, any one selected from among silver (Ag), aluminum (Al), molybdenum (Mo), gold (Au), magnesium (Mg), ytterbium (Yb), and strontium (Sr) or an alloy of two or more thereof.

The intermediate layer 162 on the first electrode 161 may include a first common layer CML1 related to holes, including a hole injection layer HIL and a hole transport layer HTL, a light emitting layer EML, a hole blocking layer HBL, and a second common layer CML2 related to electrons, including an electron transport layer ETL and an electron injection layer EIL.

A light shielding bank 170 may be provided so as to cover the edge of the first electrode 161, and an opening in the light shielding bank 170 on the first electrode 161 may be defined as a light emitting portion. The light shielding bank 170 may include a shielding organic insulating material to maintain a certain vertical thickness. The shielding organic insulating material of the light shielding bank 170 may have a vertical thickness of, for example, 1 μm to 5 μm.

A transparent bank 180 may be further provided on the light shielding bank 170 in order to protect the light shielding bank 170 and prevent introduction of impurities. The transparent bank 180 may be selectively provided on the light shielding bank 170 so as to function as a spacer.

The spacer may be further provided on the light shielding bank 170. The spacer may be locally disposed on a part of an upper surface of the light shielding bank 170, rather than on the entirety of the upper surface of the light shielding bank 170, to prevent collapse of the light shielding bank 170 under the spacer or a lower configuration when a deposition mask is applied to the substrate 111 during deposition of the intermediate layer 162.

The intermediate layer 162 may include a plurality of functional layers along with the light emitting layer. For example, the intermediate layer 162 may include a hole injection layer, a hole transport layer, a light emitting layer, an electron transport layer, and an electron injection layer. The intermediate layer 162 may be formed in a tandem structure including a plurality of stacks, each including a hole transport layer, a light emitting layer, and an electron transport layer, and a charge generation layer provided between the stacks. The charge generation layer may include, for example, an n-type charge generation layer and a p-type charge generation layer.

The subpixels SP represent individual colors through the light emitting devices 160, and the light emitting layer may be patterned and disposed on each subpixel SP using a deposition mask including an opening corresponding to the light emitting portion for each subpixel.

Functional layers other than the light emitting layer, such as a hole injection layer, a hole transport layer, an electron transport layer, an electron injection layer, and a charge generation layer, are commonly included in the plurality of subpixels. In addition, the second electrode 163 may also be commonly included in the plurality of subpixels.

The second electrode 163 may be formed by thinning a transmissive electrode made of ITO or IZO or a reflective-transmissive electrode made of silver, a silver alloy, magnesium, a magnesium alloy, ytterbium (Yb), or an ytterbium alloy.

A capping layer (not shown) may be further formed on the second electrode 163 to protect the second electrode 163 of the light emitting device 160 and to increase light emission efficiency in an upward direction.

An encapsulation layer 190 may be provided on the second electrode 163 to prevent permeation of moisture into internal components and to protect the internal components from external air.

In one or more embodiments, the encapsulation layer 190 may include a structure in which a first inorganic encapsulation layer 191, an organic encapsulation layer 192, and a second inorganic encapsulation layer 193 are stacked.

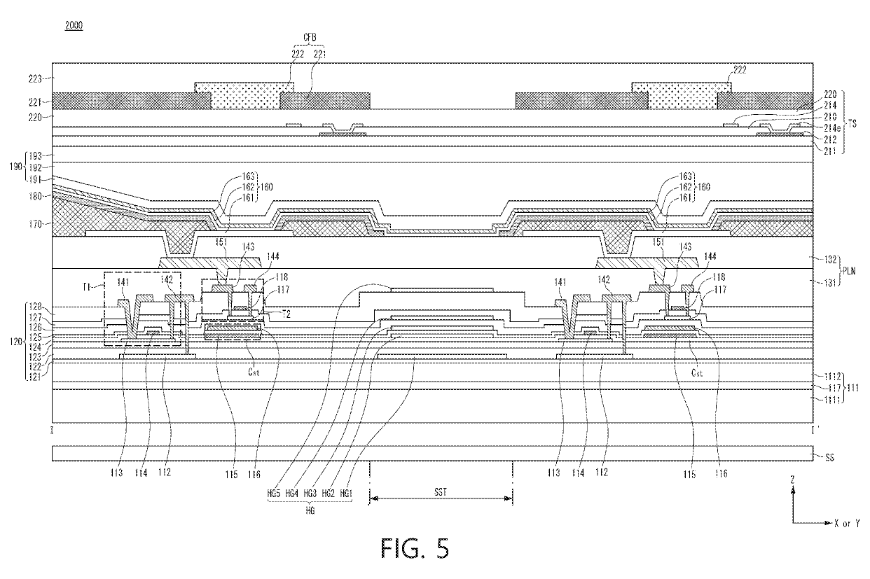

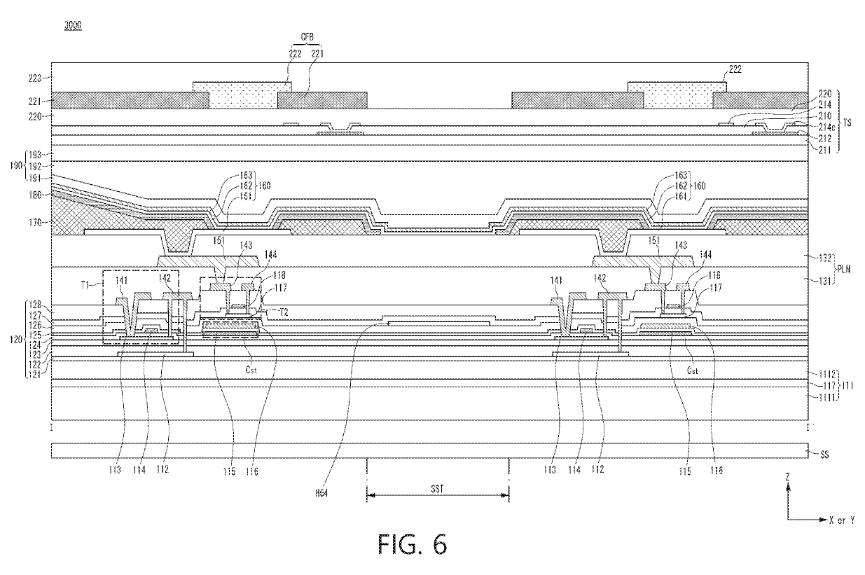

FIGS. 5 and 6 are sectional views showing a display device according to one or more other embodiments of the present disclosure.

The display device 2000 of FIG. 5 further includes a touch sensor TS and a color filter array CFB in addition to the structure of the display device 1000 of FIG. 4.

The configurations that are not included in FIG. 4 will be described below.

As shown in FIG. 5, a touch sensor including a first touch electrode layer 212 and second touch electrode layers 214e and 214 is formed on the encapsulation layer 190.

The touch sensor may be disposed on the encapsulation layer 190 in the active area AA to sense touch input. The touch sensor may detect external touch information using a user’s finger or a touch pen. The touch sensor may include a touch buffer layer 211, a first touch electrode layer 212, a touch intermediate insulating layer 210, second touch electrode layers 214e and 214, and a touch protective layer 220.

Each of the touch buffer layer 211 and the touch intermediate insulating layer 210 may be made of an inorganic material such as silicon nitride (SiNx), silicon oxide (SiOx), or silicon oxynitride (SiONx), but embodiments of the present disclosure are not limited thereto.

In the touch sensor, the first touch electrode layer 212 and the second touch connection electrode 214e, which are located on different layers, may be connected to each other and used as a first touch sensor Tx. The second touch electrode layer 214 separated from the second touch connection electrode 214e may be electrically spaced apart from the first touch sensor Tx and used as a second touch sensor Rx. A touch sensing signal may be applied to one of the first touch sensor Tx and the second touch sensor Rx, and a change due to touch may be sensed through the other.

The first and second touch sensors Tx and Rx may be disposed overlapping the light shielding bank 170. For example, the first touch sensor Tx may be disposed in the X-axis direction, and the second touch sensor Rx may be disposed in the Y-axis direction. Alternatively, the first and second touch sensors Tx and Rx may be disposed in the Y-axis and X-axis directions.

Each of the first and second touch electrode layers 212, 214e, and 214 may be made of a metal material, but embodiments of the present disclosure are not limited thereto.

The color filter array CFB may further include a black matrix 221 overlapping the light shielding bank 170 and a color filter 222 overlapping the opening of the light shielding bank 170.

A protective layer 223 configured to protect an upper surface of the display device 2000 while covering the black matrix 221 and the color filter 222 may be provided.

In the display device 2000 according to one or more other embodiments of the present disclosure, the black matrix 221 and the color filter 222 enable color expression of the light emitting portion of each subpixel of the light emitting device, wherein the black matrix 221 has light absorptivity in the visible spectrum, and the color filter 222 may block light in the remaining wavelength range other than the transmission wavelength of a predetermined color. Therefore, even if external light enters through the protective layer 223, light may be blocked in the area where the black matrix 221 is disposed, and the remaining light outside the wavelength range with selective transmittance may be blocked in the area where the color filter 222 is provided, thereby reducing the amount of external light entering the light emitting device side and thus enabling both color transmittance and external light reflection functions. Therefore, when the color filter array CFB is provided, a separate polarizer may be omitted.

In the display device according to one or more embodiments of the present disclosure, the light shielding bank 170 is provided around the light emitting device 160 to block light external light incident in a diagonal direction, thereby more effectively preventing the visibility of external light reflection.

In the display device 3000 of FIG. 6, the light transmissive hydrogen collection pattern HG4 is constituted by the same layer as the second active layer 117, which is an oxide semiconductor layer, compared to the display device 2000 of FIG. 5.

In the display device 3000 of FIG. 6, light transmission is possible, and an oxide semiconductor component that is resistant to moisture and oxygen is applied, compared to the display device 2000 of FIG. 5. In addition, since there are no metal components in the overlapping structure other than the light transmissive hydrogen collection pattern HG4, it is not necessary to apply a process for removing separate metals, thereby minimizing or at least reducing the number of processes and maintaining a high light reception rate of the light reception portion SST of the sensor SS.

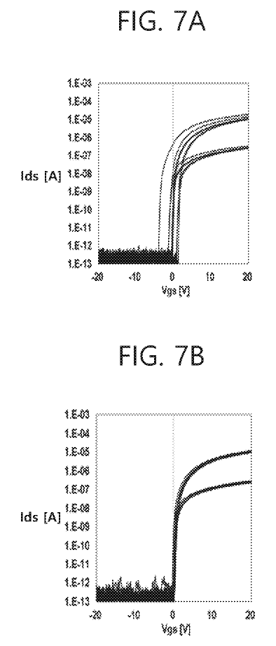

FIGS. 7A and 7B show I-V graphs of surrounding transistors when a hydrogen collection pattern is not applied and when a hydrogen collection pattern is applied.

As shown in FIG. 7A, when the hydrogen collection pattern is not applied, the dispersion range of the I-V characteristics of the transistor becomes large, and the threshold voltage range reaches -0.74 V to 1.64 V, and there is a severe negative shift in the threshold voltage. However, as shown in FIG. 7B, when the hydrogen collection pattern is applied, the dispersion range of the I-V characteristics of the transistor is reduced, and the threshold voltage is reduced to -0.11 to 0.67 V. This means that, as in the display device according to one or more embodiments of the present disclosure, the threshold voltage collection dispersion is reduced in the plurality of transistors disposed on the substrate, and the transistor characteristics are stabilized.

Meanwhile, when the hydrogen collection pattern is not provided, hydrogen components act as conductive particles in the transistor, causing the channel to become conductive, which may result in panel abnormalities such as bright spots and poor operation.

In the display device according to one or more embodiments of the present disclosure, when the light transmissive hydrogen collection pattern is applied, the light receiving ability of the sensor unit is not impaired, and the hydrogen collection characteristics are secured, thereby stabilizing the characteristics of the transistors around the sensor.

In the display device according to one or more embodiments of the present disclosure, hydrogen remaining in the insulating layer, etc. is collected by the light transmissive hydrogen collection pattern, whereby the transistor is not affected by the hydrogen remaining in the insulating layer, etc., and thus the reliability of the transistor may be improved.

In the display device according to one or more embodiments of the present disclosure, the light transmissive hydrogen collection pattern is provided so as to overlap the sensor unit, whereby it is possible to maintain the light receiving capability of the sensor unit in the active area and to stabilize the characteristics of the transistors around the sensor unit. Hydrogen is not transmitted to the transistors around the light receiving portion of the sensor unit but is captured by the hydrogen collection pattern, thereby improving the reliability of the transistors around the sensor unit.

As is apparent from the above description, a display device according to the present disclosure has the following effects.

The display device according to one or more embodiments of the present disclosure is provided with a light transmissive hydrogen collection pattern, whereby it is possible to maintain the light receiving ability of a sensor unit provided in an active area and to stabilize the characteristics of transistors around the sensor unit.

In the display device according to one or more embodiments of the present disclosure, hydrogen remaining in an insulating layer, etc. is collected by the light transmissive hydrogen collection pattern, whereby the transistors are not affected by the hydrogen remaining in the insulating layer, etc. and thus the reliability of transistors may be improved.

In the display device according to one or more embodiments of the present disclosure, the hydrogen collection pattern is provided adjacent to the transistors disposed in the area surrounding the light receiving portion of the sensor unit, whereby hydrogen is not transmitted to the transistors around the light receiving portion of the sensor unit, and the hydrogen collection pattern captures the hydrogen, thereby improving the reliability of the transistors around the sensor unit.

In the display device according to one or more embodiments of the present disclosure, the hydrogen collection pattern is provided in a plurality of pattern layers, thereby preventing the influence of hydrogen remaining in each insulating layer.

In the display device according to one or more embodiments of the present disclosure, a part of the hydrogen collection pattern is made of a metal, wherein, after collecting residual hydrogen in a subsequent process, the hydrogen collection pattern overlapping the sensor unit is removed in a subsequent metal etching process, whereby it is possible to maintain the light receiving characteristics of the sensor unit. A display device according to one or more embodiments of the present disclosure may comprise a substrate comprising an active area comprising a sensor unit and a non-active area surrounding the active area, a sensor under the substrate corresponding to the sensor unit, a light emitting device at the active area, the light emitting device comprising a plurality of first electrodes, an intermediate layer comprising a light emitting layer, and a second electrode, a transistor between the substrate and the light emitting device and a light transmissive hydrogen collection pattern on the substrate to overlap the sensor.

In a display device according to one or more embodiments of the present disclosure, the light transmissive hydrogen collection pattern may comprise a plurality of pattern layers on different insulating layers.

In a display device according to one or more embodiments of the present disclosure, the plurality of pattern layers may overlap each other.

In a display device according to one or more embodiments of the present disclosure, the transistor may comprise an oxide semiconductor, and the light transmissive hydrogen collection pattern may comprise a first pattern on a same layer as the oxide semiconductor.

In a display device according to one or more embodiments of the present disclosure, the light transmissive hydrogen collection pattern may comprise a second pattern disposed on a different layer from the first pattern.

In a display device according to one or more embodiments of the present disclosure, the light transmissive hydrogen collection pattern may comprise an oxide semiconductor.

In a display device according to one or more embodiments of the present disclosure, the oxide semiconductor may comprise at least one metal among indium, gallium, zinc, and tungsten.

In a display device according to one or more embodiments of the present disclosure, the light transmissive hydrogen collection pattern may comprise a metal having light transmissivity in a visible light wavelength range.

In a display device according to one or more embodiments of the present disclosure, the light transmissive hydrogen collection pattern may comprise a semiconductor or metal having an energy bandgap of 3.2 eV or more.

A display device according to one or more embodiments of the present disclosure may further comprise a light shielding bank configured to define a light emitting portion of each of the plurality of first electrodes.

In a display device according to one or more embodiments of the present disclosure, at the sensor unit, the light transmissive hydrogen collection pattern may not overlap the light shielding bank.

In a display device according to one or more embodiments of the present disclosure, the light transmissive hydrogen collection pattern may correspond to an opening of the light shielding bank.

In a display device according to one or more embodiments of the present disclosure, the light transmissive hydrogen collection pattern may overlap a light receiving portion of the sensor unit.

In a display device according to one or more embodiments of the present disclosure, the sensor unit may comprise an ambient light sensor.

In a display device according to one or more embodiments of the present disclosure, first subpixels overlapping the sensor unit and second subpixels outside the sensor unit may have the same resolution.

In the display device according to one or more embodiments of the present disclosure, it is possible to improve reliability by maintaining the transistor threshold voltage dispersion range within a certain range, thereby improving the reliability of the device and achieving operational stability. In the display device presented herein, therefore, continuous applicability is possible, whereby ESG (environmental/social/governance) goals may be achieved.

What is claimed is:

1. A display device, comprising:
a substrate including an active area with a sensor unit and a non-active area surrounding the active area;
a sensor under the substrate corresponding to the sensor unit;
a light emitting device at the active area, the light emitting device comprising a plurality of first electrodes, an intermediate layer including a light emitting layer, and a second electrode;
a transistor between the substrate and the light emitting device; and
a light transmissive hydrogen collection pattern on the substrate, the light transmissive hydrogen collection pattern overlapping the sensor.

2. The display device according to claim 1, wherein the light transmissive hydrogen collection pattern comprises a plurality of pattern layers on different insulating layers.

3. The display device according to claim 2, wherein the plurality of pattern layers overlap each other.

4. The display device according to claim 1, wherein the transistor comprises an oxide semiconductor, and
wherein the light transmissive hydrogen collection pattern comprises a first pattern on a same layer as the oxide semiconductor.

5. The display device according to claim 4, wherein the light transmissive hydrogen collection pattern comprises a second pattern disposed on a different layer from the first pattern.

6. The display device according to claim 1, wherein the light transmissive hydrogen collection pattern comprises an oxide semiconductor.

7. The display device according to claim 6, wherein the oxide semiconductor comprises at least one metal among indium, gallium, zinc, and tungsten.

8. The display device according to claim 1, wherein the light transmissive hydrogen collection pattern comprises a metal having light transmissivity in a visible light wavelength range.

9. The display device according to claim 1, wherein the light transmissive hydrogen collection pattern comprises a semiconductor or metal having an energy bandgap of 3.2 eV or more than 3.2 eV.

10. The display device according to claim 1, further comprising a light shielding bank configured to define a light emitting portion of each of the plurality of first electrodes.

11. The display device according to claim 10, wherein, at the sensor unit, the light transmissive hydrogen collection pattern does not overlap the light shielding bank.

12. The display device according to claim 10, wherein the light transmissive hydrogen collection pattern corresponds to an opening in the light shielding bank.

13. The display device according to claim 1, wherein the light transmissive hydrogen collection pattern overlaps a light receiving portion of the sensor unit.

14. The display device according to claim 13, wherein the sensor unit comprises an ambient light sensor.

15. The display device according to claim 1, wherein first subpixels overlapping the sensor unit and second subpixels outside the sensor unit have a same resolution.

16. A display device, comprising:
a substrate including an active area and a non-active area surrounding the active area, wherein a plurality of subpixels are disposed in the active area;
a sensor disposed under the substrate and further from a first subpixel of the plurality of subpixels than the substrate in a cross-sectional view of the display device, wherein the first subpixel comprises:
a light emitting device configured to emit light, and
a driving transistor for driving the light emitting device, the driving transistor disposed between the substrate and the light emitting device in the cross-sectional view, the driving transistor including a gate electrode, a source electrode, a drain electrode, and an active layer overlapping the gate electrode and connected to the source electrode and the drain electrode; and
one or more light transmissive hydrogen collection patterns overlapping a light receiving portion of the sensor,
wherein a first hydrogen collection pattern of the one or more light transmissive hydrogen collection patterns is on a same layer as the active layer of the driving transistor.

17. The display device according to claim 16, wherein the first subpixel further comprises a switching transistor coupled to the driving transistor and between the substrate and the light emitting device in the cross-sectional view,
wherein a shielding pattern is connected to the switching transistor and is closer to the substrate than the switching transistor in the cross-sectional view, the shielding pattern blocking light from the substrate to reach the switching transistor, and
wherein a second light transmissive hydrogen collection pattern of the one or more light transmissive hydrogen collection patterns is on a same layer as the shielding pattern.

18. The display device according to claim 17, wherein a third light transmissive hydrogen collection pattern of the one or more light transmissive hydrogen collection patterns is on a same layer as a gate electrode of the switching transistor.

19. The display device according to claim 16, wherein the first subpixel further comprises a storage capacitor coupled to the driving transistor, the storage capacitor including a first storage electrode and a second storage electrode further from the substrate than the first storage electrode in the cross-sectional view, and
wherein a fourth light transmissive hydrogen collection pattern of the one or more light transmissive hydrogen collection patterns is on a same layer as the second storage electrode.

20. The display device according to claim 16, wherein a fifth light transmissive hydrogen collection pattern of the one or more light transmissive hydrogen collection patterns is on a same layer as the source electrode and the drain electrode of the driving transistor.
